(19) United States
(12) Patent Application Publication
(10) Pub. No.: US 2026/0255556 A1
(43) Pub. Date: Aug. 27, 2026

(54) TRACTION INVERTER COMPONENT COOLING

(71) Applicant: GM GLOBAL TECHNOLOGY OPERATIONS LLC., Detroit, MI (US)

(72) Inventors: Selina X. Zhao, Rochester Hills, MI (US); Mark R. Claywell, Birmingham, MI (US); Roshan Kandanda, Sterling Heights, MI (US); Muhammad A. Zahid, Troy, MI (US); Khorshed Mohammed Alam, Canton, MI (US)

(73) Assignee: GM GLOBAL TECHNOLOGY OPERATIONS LLC, Detroit, MI (US)

(21) Appl. No.: 19/065,241

(22) Filed: Feb. 27, 2025

(51) Int. Cl. H05K 7/20; H01L 23/467; H02M 7/00

(52) U.S. Cl. CPC H05K 7/20918; H02M 7/003; H05K 7/20145; H05K 7/20945; H10W 40/43

(57) ABSTRACT

A traction inverter of a vehicle includes a housing, a plurality of power transistors, a plurality of flow guides, and a plurality of busbars. The plurality of power transistors, the plurality of busbars and the plurality of flow guides are disposed within the housing. The housing that defines a first axis and an outlet vent. The plurality of flow guides isolate the plurality of power transistors pneumatically from the plurality of busbars and direct an airflow across the plurality of busbars in a direction parallel to the first axis and out of the housing through the outlet vent.

### INTRODUCTION

The present disclosure relates to a system and systems and methods for traction inverter component cooling.

Many traction inverters in the industry lack a pressure relief vent to manage a pressure differential within a cavity and a condensation build up. Air within the traction inverters remains stagnant at relatively high temperatures while operating at peak conditions in the range of 100° to 105° Celsius. Components inside the traction inverters produce heat but do not receive active cooling or little to no passive cooling. Often due to the stagnant air within the traction inverter, the components see excessive localized heating and as a result experience a shortened life due to accelerated thermal fatigue. Alternatively, the components are oversized/over designed to manage the localized thermal loads.

Accordingly, those skilled in the art continue with research and development efforts in the field of cooling components inside traction inverters in vehicles.

### SUMMARY

A traction inverter of a vehicle is provided herein. The traction inverter includes a housing that defines a first axis and an outlet vent, a plurality of power transistors disposed within the housing, a plurality of busbars disposed within the housing, and a plurality of flow guides disposed within the housing. The plurality of flow guides isolate the plurality of power transistors pneumatically from the plurality of busbars, and direct an airflow across the plurality of busbars in a direction parallel to the first axis and out of the housing through the outlet vent.

In one or more embodiments of the traction inverter, the housing further defines an inlet vent, and the plurality of flow guides further direct the airflow into the housing through the inlet vent and toward the plurality of busbars.

In one or more embodiments of the traction inverter, the first axis is oriented approximately vertically in the vehicle, the inlet vent is physically below the outlet vent, and the airflow is solely a convection airflow.

In one or more embodiments, the traction inverter includes one or more piezoceramic materials disposed approximate one or more of the inlet vent and the outlet vent and operational to vibrate in response to a control signal, and one or more flexible flaps coupled to the one or more piezoceramic materials and operational to push air through the one or more of the inlet vent and the outlet vent.

In one or more embodiments, the traction inverter includes one or more one-way release valves disposed respectively in one or more of the inlet vent and the outlet vent, wherein the one or more one-way release valves are operational to control the airflow through the one or more of the inlet vent and the outlet vent.

In one or more embodiments, the traction inverter includes a heat spreader thermally coupled to the plurality of power transistors and operational to remove heat from the plurality of power transistors, and a coolant block thermally coupled to the heat spreader and operational to remove the heat from the heat spreader. The plurality of flow guides further direct the airflow through the coolant block.

In one or more embodiments of the traction inverter, the coolant block includes double-sided air heatsink thermally coupled to the heat spreader and operational to transfer at least part of the heat to the airflow, and the double-sided air heatsink is oriented to direct the airflow perpendicular to the first axis.

In one or more embodiments of the traction inverter, the first axis is oriented approximately vertically in the vehicle, and the coolant block and the outlet vent are disposed above the plurality of power transistors.

In one or more embodiments, the traction inverter includes the first axis is oriented approximately vertically in the vehicle, and the coolant block and the outlet vent are disposed above the plurality of power transistors.

A method for cooling components in a traction inverter in a vehicle is provided herein. The method includes isolating a plurality of power transistors pneumatically from a plurality of busbars with a plurality of flow guides. A housing of the traction inverter defines a first axis and an outlet vent. The plurality of power transistors are disposed within the housing. The plurality of busbars are disposed within the housing. The plurality of flow guides are disposed within the housing. The method includes directing an airflow with the plurality of flow guides across the plurality of busbars in a direction parallel to the first axis and out of the housing through the outlet vent.

In one or more embodiments of the method, the housing further defines an inlet vent, and the plurality of flow guides further direct the airflow into the housing through the inlet vent and toward the plurality of busbars.

In one or more embodiments of the method, the first axis is oriented approximately vertically in the vehicle, the inlet vent is physically below the outlet vent, and the airflow is solely a convection airflow.

In one or more embodiments, the method includes vibrating one or more piezoceramic materials in response to a control signal, wherein the one or more piezoceramic materials are disposed approximate one or more of the inlet vent and the outlet vent, and pushing air through the one or more of the inlet vent and the outlet vent with one or more flexible flaps, wherein the one or more flexible flaps are coupled to the one or more piezoceramic materials.

In one or more embodiments, the method includes controlling the airflow through one or more of the inlet vent and the outlet vent with one or more one-way release valves, wherein the one or more of the one-way release valves are disposed respectively in the one or more of the inlet vent and the outlet vent.

In one or more embodiments, the method includes removing heat from the plurality of power transistors with a heat spreader thermally coupled to the plurality of power transistors, removing the heat from the heat spreader with a coolant block thermally coupled to the heat spreader, and further directing the airflow through the coolant block with the plurality of flow guides.

In one or more embodiments, the method includes transferring at least part of the heat to the airflow with a double-sided air heatsink in the coolant block. The double-sided air heatsink is thermally coupled to the heat spreader. The double-sided air heatsink is oriented to direct the airflow perpendicular to the first axis.

In one or more embodiments of the method, the first axis is oriented approximately vertically in the vehicle, and the coolant block and the outlet vent are disposed above the plurality of power transistors.

In one or more embodiments, the method includes receiving at least part of the heat from the heat spreader at a cooling plate thermally coupled to the heat spreader. The housing further includes a plurality of coolant ports in fluid communication with the cooling plate.

A vehicle is provided herein. The vehicle includes a battery pack operational to present a direct current, a traction motor operational to generate a torque in response to an alternating current, and a traction inverter electrically coupled between the battery pack and the traction motor and operational to convert the direct current into the alternating current. The traction inverter includes a housing that defines a first axis, an inlet vent, and an outlet vent; a plurality of power transistors disposed within the housing; a plurality of busbars disposed within the housing; and a plurality of flow guides disposed within the housing. The plurality of flow guides isolate the plurality of power transistors pneumatically from the plurality of busbars, and direct an airflow into the housing through the inlet vent, across the plurality of busbars in a direction parallel to the first axis and out of the housing through the outlet vent.

In one or more embodiments of the vehicle, the first axis is oriented approximately vertically in the vehicle, the inlet vent is physically below the outlet vent, and the airflow is solely a convection airflow.

The above features and advantages and other features and advantages of the present disclosure are readily apparent from the following detailed description of the best modes for carrying out the disclosure when taken in connection with the accompanying drawings.

### BRIEF DESCRIPTION OF THE DRAWINGS

FIG. 1 is a schematic plan diagram illustrating a context of a system is shown in accordance with one or more exemplary embodiments.

FIG. 2 is a schematic cut-away plan diagram of embodiment of a traction inverter in accordance with one or more exemplary embodiments.

FIG. 3 is a schematic cut-away plan diagram of another embodiment of a traction inverter in accordance with one or more exemplary embodiments.

FIG. 4 is a schematic diagram of an electrically driven piezo-electric flap accordance with one or more exemplary embodiments.

FIG. 5 is a schematic cut-away plan diagram of yet another embodiment of a traction inverter in accordance with one or more exemplary embodiments.

FIG. 6 is a schematic side diagram of a portion of the traction inverter in accordance with one or more exemplary embodiments.

### DETAILED DESCRIPTION

Embodiments of the disclosure generally provide systems and/or methods to enhance air cooling performance of traction inverters. Components such as busbars, discharge resistors, DC-link capacitors, microprocessors, and other low-voltage components within the traction inverters do not receive direct or passive cooling from coolant blocks and so may result in heat accumulation and moisture condensation. The traction inverter designs disclosed herein provide molded-in, flow guide features that allow air to circulate within traction inverter housings with few or no active cooling components. The housings may include an outlet vent to expel heated, moist air. An optional inlet vent may be implemented to transfer cooling air into the housings. In various embodiments, the flow guides within the housings may pneumatically isolate the components from power transistors to aid in thermal control of the components.

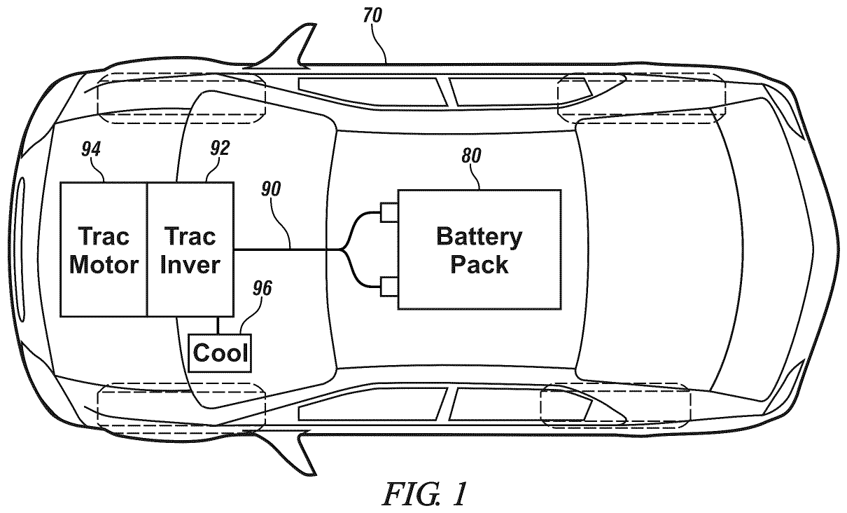

Referring to FIG. 1, a schematic plan diagram illustrating a context of a system is shown in accordance with one or more exemplary embodiments. The system may implement a vehicle 70. The vehicle 70 generally comprises a battery pack 80, a harness 90, a traction inverter 92, a traction motor 94, and a cooling system 96.

The vehicle 70 may include, but is not limited to, mobile objects such as a passenger vehicle, a truck, an autonomous vehicle, an electric-powered vehicle, a hybrid vehicle, a motorcycle, a boat, a farm vehicle, a train and/or an aircraft. In some embodiments, the vehicle 70 may include stationary objects such as billboards, kiosks and/or marquees. Other types of vehicles 70 may be implemented to meet the design criteria of a particular application.

The battery pack 80 implements a high-voltage battery pack configured to store electrical energy. The battery pack 80 is generally operational to provide electrical power to the traction inverter 92. The battery pack 80 may include multiple battery modules electrically connected in series and/or in parallel. In various embodiments, the battery pack 80 may provide approximately 400 to 1000 volts direct current (DC) electrical potential. Other battery voltages may be implemented to meet the design criteria of a particular application.

The harness 90 implements an electrical harness. The harness 90 is generally operational to carry electrical power from the battery pack 80 to the traction inverter 92.

The traction inverter 92 implements a DC-to-AC converter. The traction inverter 92 is generally operational to convert the DC electrical power received from the battery pack 80 into alternating current (AC) electrical power utilized by the traction motor 94.

The traction motor 94 implements an electric motor. In various embodiments, the traction motor 94 is a multi-phase (e.g., 3 phase) AC motor. The traction motor 94 is generally operational to provide rotation and torque to drive wheels of the vehicle 70. The electrical power consumed by the traction motor 94 may be provided by the battery pack 80 and/or an alternator of the vehicle 70.

The cooling system 96 implements a liquid cooling system. The cooling system 96 is operational to remove excess heat from the traction inverter 92. In various embodiments, the liquid may be a water-based fluid. The excess heat may be transferred to an atmosphere around the vehicle 70 and/or a frame of the vehicle 70.

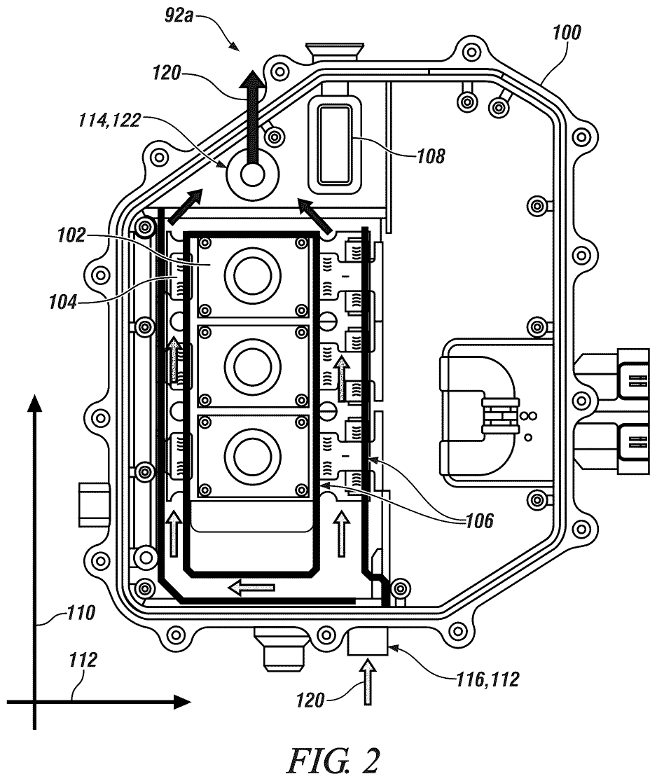

Referring to FIG. 2, a schematic cut-away plan diagram of an example implementation of an embodiment of a traction inverter 92a is shown in accordance with one or more exemplary embodiments. The traction inverter 92a may be a variation of the traction inverter 92 shown in FIG. 1. The traction inverter 92a generally includes a housing 100, multiple power transistors 102, multiple busbars 104, multiple flow guides 106, and other electrical components 108. The housing 100 may define a first axis 110, a second axis 112, an outlet vent 114, and an optional inlet vent 116.

The traction inverter 92a may have two vents and internal flow guide features along the low voltage components such as the busbars 104, printed circuit board components, and the like, to increase convectional cooling. In various embodiments, the vents 114 and 116, and flow guides 106 may be co-molded (e.g., molded in) as a part of the composite housing 100. In other embodiments, the vents 114 and 116 may be snap-in assembled parts. Other fabrication techniques may be implemented to meet the design criteria of a particular application.

The locations of the two vents 114 and 116 may be located between the flow guides 106 to allow to draw in air into the housing 100 and to extract air out of the housing 100. The vents 114 and 116 are placed to take advantage of natural convection, cooler air is drawn from the outside and as the air heats up due to the thermal loads, the air rises and is vented out from the top outlet vent 114. In particular, an airflow 120 enters the housing 100 through the inlet vent 116, is routed through the traction inverter 92a by the flow guides 106, and exits through the outlet vent 114. Therefore, the inlet vent 116 is physically below the outlet vent 114.

Molded-in flow guides 106 placed over the select low voltage electrical components such as resistors and the busbars 104 allow the release of the thermal loads from stagnant heated air from low voltage components. The airflow 120 passes over the busbars 104 and the other electrical components 108 to aid in removing heat generated by the busbars 104 and the other electrical components 108. In various embodiments, the flow guides 106 may pneumatically isolate the airflow 120 from the power transistors 102, which are primarily cooled by other structures. The pneumatic isolation helps prevent heat from the power transistors 102 from being thermally conveyed through the air to the busbars 104 and the other electrical components 108.

The ambient temperature of the traction inverter 92a may be reduced by passively cycling the air while maintaining ingress protection ratings. While the traction inverter 92a is mounted vertically (the first axis is pointing generally upward (±10 degrees, ±5 degrees, or less than vertical) in the vehicle 70 (FIG. 1), the airflow 120 is a convection current with the components 108 and busbars 104 warming the air inside the housing 100. The inlet vent 116 and the outlet vent 114 allow for air pressure to equalize while allowing moisture to exit the housing 100 via a one-way release valve (or membrane) 122. The traction inverter 92a may be characterized by the absence of a motor and fan to more the air through the housing 100.

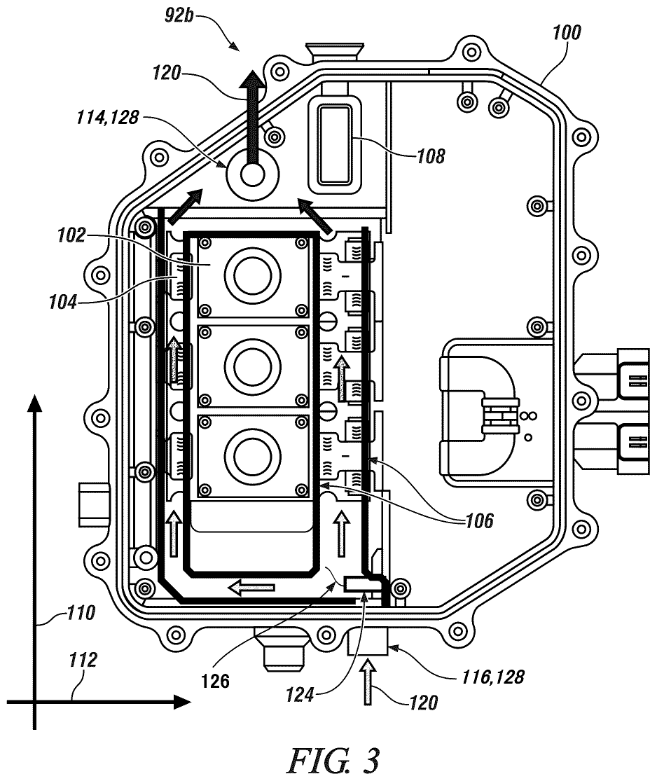

Referring to FIG. 3, a schematic cut-away plan diagram of an example implementation of another embodiment of a traction inverter 92b is shown in accordance with one or more exemplary embodiments. The traction inverter 92b may be a variation of the traction inverter 92 shown in FIG. 1 and/or the traction inverter 92a shown in FIG. 2. The traction inverter 92b generally includes the housing 100, the multiple power transistors 102, the multiple busbars 104, the multiple flow guides 106, the other electrical components 108, one or more piezoceramic materials 124 (one shown), and one or more flexible flaps 126. The housing 100 may define the first axis 110, the second axis 112, the outlet vent 114, and the inlet vent 116.

The traction inverter 92b may include one or two pressure driven piezo-electric flaps and the one-way release valves 128 in at least one of the vent locations to accelerate releasing the thermal stress introduced by the hot stagnant air at the low voltage components inside of the traction inverter 92b to reduce the packaging space. The traction inverter 92b may be characterized by the absence of a motor and fan to move the air through the housing 100.

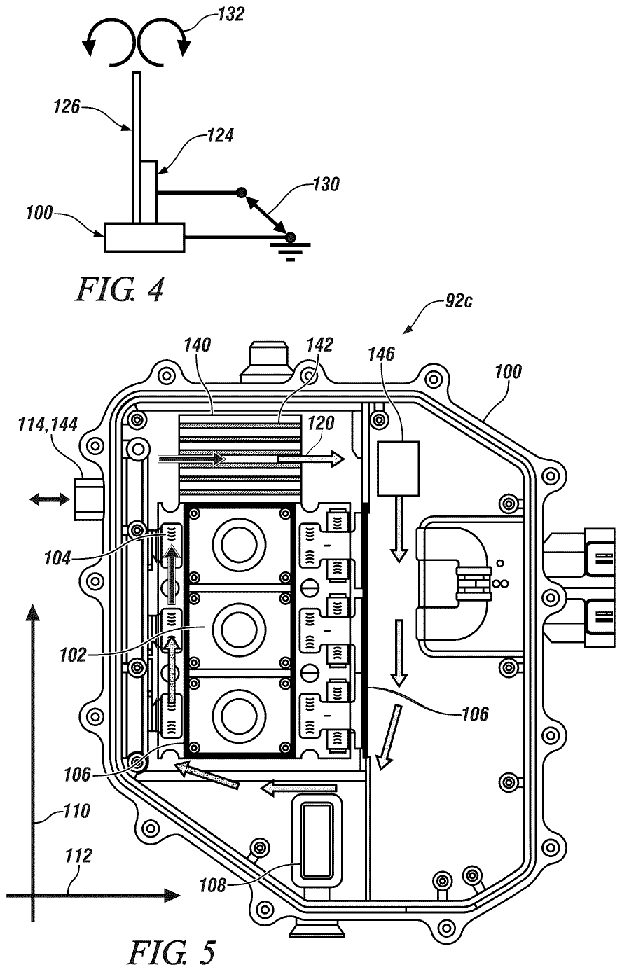

Referring to FIG. 4, a schematic diagram of an example implementation of an electrically driven piezo-electric flap is shown in accordance with one or more exemplary embodiments. To further accelerate the convection action, a piezoceramic material 124 and a flexible flap 126 may be applied near the inlet vent 116 or the outlet vent 114 to actively push air in and/or out of the housing 100 (e.g., pressure pulsations). The piezoceramic driver may also be integrated on an electronic control board within the housing 100. An alternating electrical control signal 130 may be applied between the piezoceramic material 124 and the housing 100 to set the piezoceramic material 124 in a vibrating motion. The flexible flap 126 transfers the vibrating motion to the surrounding air 132 to push the surrounding air 132 inside the housing 100, through the inlet vent 116 and/or the outlet vent 114, thereby increasing the airflow 120 (FIG. 3) through the housing 100. The one-way release valves 122 and the moving flexible flap 126 generally work together to generate a net airflow through the housing 100 and/or an airflow inside the housing 100. Other apparatuses that can push air to cool components may be implemented to meet the design criteria of a particular application.

Referring to FIG. 5, a schematic cut-away plan diagram of an example implementation of yet another embodiment of a traction inverter 92c is shown in accordance with one or more exemplary embodiments. The traction inverter 92c may be a variation of the traction inverter 92 shown in FIG. 1, the traction inverter 92a shown in FIG. 2 and/or the traction inverter 92b shown in FIG. 3. The traction inverter 92c generally includes the housing 100, the multiple power transistors 102, the multiple busbars 104, the multiple flow guides 106, the other electrical components 108, a coolant block 140, and a double-sided air heatsink 142 within the coolant block 140. The housing 100 may define the first axis 110, the second axis 112, and the outlet vent 114. A pressure release (or relief) valve 144 is disposed at the outlet vent 114 to prevent overall pressurized heat accumulation from becoming too great. The sole pressure release valve 144 is operational to balance air pressure and perform humidity control.

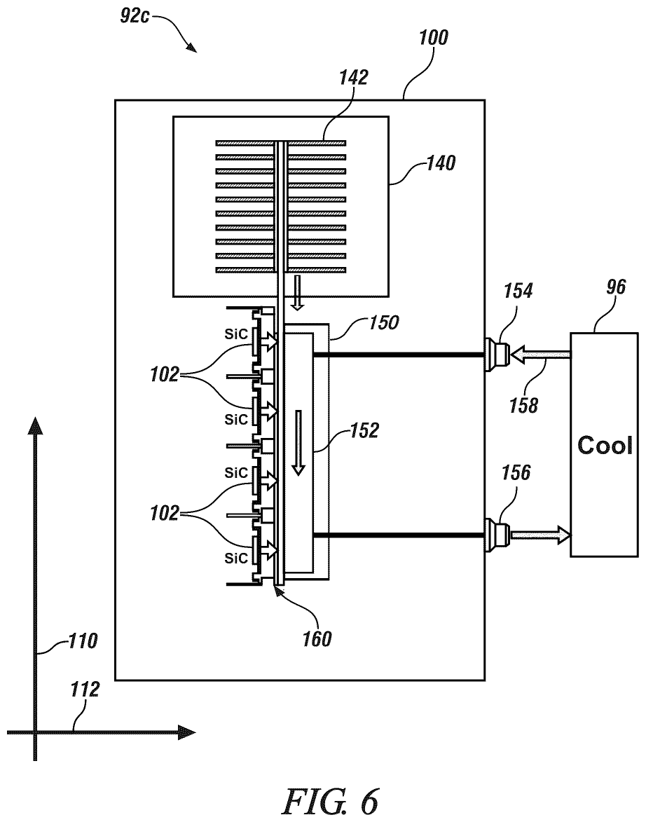

The coolant block 140 and the double sided air heatsink 142 in the traction inverter 92c are operational to actively cool down internal ambient air using guided heat spreaders (FIG. 6) to cool the busbars 104 and other electrical components 108. A turbulator 146 may be included to induce convection airflow 120 within the traction inverter 92c.

Referring to FIG. 6, a schematic side diagram of a portion of the traction inverter 92c is shown in accordance with one or more exemplary embodiments. The traction inverter 92c include the cooling system 96, the housing 100, the coolant block 140, and the double-sided air heatsink 142. The traction inverter 92c further includes a heat spreader 150, a cooling plate 152, a coolant inlet port 154, and a coolant outlet port 156. One or more heat spreaders 150 may be sandwiched between the double-sided air heatsink 142. A cold inlet coolant 158 may come in from either end of the cooling plate 152. In various embodiments, the cold inlet coolant 158 comes in nearest the double-sided air heatsink 142 (as shown) to provide a largest temperature delta between the air and the double-sided air heatsink 142. Fins or pins of the double-sided air heatsink 142 may be oriented perpendicular to the first axis 110.

The cooling system 96 is in fluid communication with the cooling plate 152. The cooling system 96 circulates the cold inlet coolant 158 from the coolant inlet port 154, through the cooling plate 152 and out the coolant outlet port 156. In various embodiments, the coolant ports 154 and 156 may be formed as part of the housing 100. A thermal conductive bonding tape 160 is used at an interface of power transistors 102, the busbars 104 (FIG. 5) and heat spreader 150 to provide thermal coupling. The heat spreader 150 is operational to remove heat from the power transistors 102 and the busbars 104.

Embodiments of the system generally provide a traction inverter design with molded-in, guided air flow features around busbars, discharge resistors, and other low-voltage components to allow air circulation. In some embodiments, the traction inverter has two molded-in vents in addition to the internal flow guide features along the low-voltage components such as busbars, printed circuit board components, and the like, to increase convectional cooling. The co-mold vents and flow guides may be fabricated as a part of the composite housing to enable parts number reduction.

In various embodiments, the traction inverter may include one or two pressure driven piezo-electric flaps/one-way valves at vent locations to accelerate releasing the thermal stress introduced by the hot stagnant air at the low-voltage components inside of the housing to reduce the packaging space by not implementing a cooling fan driven by the electrical motor. In some embodiments, the traction inverter has double sided air heatsink or a single-sided air heatsink to actively cool down internal ambient air using guided heat spreaders to cool busbars, printed circuit board components, the busbars, and the like.

The air heat sink mechanism may include more than one heat spreader fastened by double-sided thermal conductive tape that has a thermal conductivity in the range of 1.5-0.8 W/m k) or pipes. The air heat sink mechanism may also be directly brazed to the rest of the cooler assembly during the manufacturing process. The air heat sink mechanism may include double-sided cooling fins exposed to ambient to enhance cooling efficiency. An external surface of heat sink mechanism may have surface treatments, such as anodization, to increase emissivity to accentuate heat rejection.

The housing is shaped to reject localized heat accumulation and moisture condensation due to thermal stress inside of the traction inverter. Components within the traction inverter that do not directly attach to cooling mechanisms may be passively cooled with convection air. The design approach reduces component oversizing and reduces premature component failure due to thermal load and moisture accumulation.

Induce guided double side cooling features within the traction inverter may reduce hot stagnant air. The molded-in flow guides along the low-voltage components actively cool down internal ambient air using piezoelectric check inlet and outlet vents. The double-side air cooling module with guided internal air flow features aid in the cooling of the internal components. A method of forming a thermally conducting junction between the power switches (e.g., Silicon-carbide power switches) to the guided heat spreaders may include application of a double-sided tape (e.g., polyproline tape) having a thermal conductivity in the range of 1.5-0.8 W/mk.

A traction inverter of a vehicle includes a housing, multiple power transistors, multiple flow guides and multiple busbars. The power transistors, the busbars and the flow guides are disposed within the housing. The housing defines a first axis and an outlet vent. The flow guides isolate the power transistors pneumatically from the busbars. The flow guides also direct an airflow across the busbars in a direction parallel to the first axis and subsequently out of the housing through the outlet vent.

Numerical values of parameters (e.g., of quantities or conditions) in this specification, including the appended claims, are to be understood as being modified in each instance by the term “about” whether or not “about” actually appears before the numerical value. “About” indicates that the stated numerical value allows some slight imprecision (with some approach to exactness in the value; about or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of values and further divided ranges within the entire range. Each value within a range and the endpoints of a range are hereby disclosed as a separate embodiment.

While the best modes for carrying out the disclosure have been described in detail, those familiar with the art to which this disclosure relates will recognize various alternative designs and embodiments for practicing the disclosure within the scope of the appended claims.

What is claimed is:

1. A traction inverter of a vehicle comprising:
a housing that defines a first axis and an outlet vent;
a plurality of power transistors disposed within the housing;
a plurality of busbars disposed within the housing; and
a plurality of flow guides disposed within the housing, wherein the plurality of flow guides:
isolate the plurality of power transistors pneumatically from the plurality of busbars; and
direct an airflow across the plurality of busbars in a direction parallel to the first axis and out of the housing through the outlet vent.

2. The traction inverter according to claim 1, wherein:
the housing further defines an inlet vent; and
the plurality of flow guides further direct the airflow into the housing through the inlet vent and toward the plurality of busbars.

3. The traction inverter according to claim 2, wherein:
the first axis is oriented approximately vertically in the vehicle;
the inlet vent is physically below the outlet vent; and
the airflow is solely a convection airflow.

4. The traction inverter according to claim 2, further comprising:
one or more piezoceramic materials disposed approximate one or more of the inlet vent and the outlet vent and operational to vibrate in response to a control signal; and
one or more flexible flaps coupled to the one or more piezoceramic materials and operational to push air through the one or more of the inlet vent and the outlet vent.

5. The traction inverter according to claim 2, further comprising:
one or more one-way release valves disposed respectively in one or more of the inlet vent and the outlet vent, wherein the one or more one-way release valves are operational to control the airflow through the one or more of the inlet vent and the outlet vent.

6. The traction inverter according to claim 1, further comprising:
a heat spreader thermally coupled to the plurality of power transistors and operational to remove heat from the plurality of power transistors; and
a coolant block thermally coupled to the heat spreader and operational to remove the heat from the heat spreader, wherein:
the plurality of flow guides further direct the airflow through the coolant block.

7. The traction inverter according to claim 6, wherein:
the coolant block includes double-sided air heatsink thermally coupled to the heat spreader and operational to transfer at least part of the heat to the airflow; and
the double-sided air heatsink is oriented to direct the airflow perpendicular to the first axis.

8. The traction inverter according to claim 6, wherein:
the first axis is oriented approximately vertically in the vehicle; and
the coolant block and the outlet vent are disposed above the plurality of power transistors.

9. The traction inverter according to claim 6, further comprising:
a cooling plate thermally coupled to the heat spreader and operational to receive at least part of the heat from the heat spreader, wherein:
the housing further includes a plurality of coolant ports in fluid communication with the cooling plate.

10. A method for cooling components in a traction inverter in a vehicle, comprising:
isolating a plurality of power transistors pneumatically from a plurality of busbars with a plurality of flow guides, wherein:
a housing of the traction inverter defines a first axis and an outlet vent;
the plurality of power transistors are disposed within the housing;
the plurality of busbars are disposed within the housing; and
the plurality of flow guides are disposed within the housing; and
directing an airflow with the plurality of flow guides across the plurality of busbars in a direction parallel to the first axis and out of the housing through the outlet vent.

11. The method according to claim 10, wherein:
the housing further defines an inlet vent; and
the plurality of flow guides further direct the airflow into the housing through the inlet vent and toward the plurality of busbars.

12. The method according to claim 11, wherein:
the first axis is oriented approximately vertically in the vehicle;
the inlet vent is physically below the outlet vent; and
the airflow is solely a convection airflow.

13. The method according to claim 11, further comprising:
vibrating one or more piezoceramic materials in response to a control signal, wherein the one or more piezoceramic materials are disposed approximate one or more of the inlet vent and the outlet vent; and
pushing air through the one or more of the inlet vent and the outlet vent with one or more flexible flaps, wherein the one or more flexible flaps are coupled to the one or more piezoceramic materials.

14. The method according to claim 11, further comprising:
controlling the airflow through one or more of the inlet vent and the outlet vent with one or more one-way release valves, wherein the one or more of the one-way release valves are disposed respectively in the one or more of the inlet vent and the outlet vent.

15. The method according to claim 10, further comprising:
removing heat from the plurality of power transistors with a heat spreader thermally coupled to the plurality of power transistors;
removing the heat from the heat spreader with a coolant block thermally coupled to the heat spreader; and
further directing the airflow through the coolant block with the plurality of flow guides.

16. The method according to claim 15, further comprising:
transferring at least part of the heat to the airflow with a double-sided air heatsink in the coolant block, wherein:
the double-sided air heatsink is thermally coupled to the heat spreader; and
the double-sided air heatsink is oriented to direct the airflow perpendicular to the first axis.

17. The method according to claim 15, wherein:
the first axis is oriented approximately vertically in the vehicle; and
the coolant block and the outlet vent are disposed above the plurality of power transistors.

18. The method according to claim 15, further comprising:
receiving at least part of the heat from the heat spreader at a cooling plate thermally coupled to the heat spreader, wherein:
the housing further includes a plurality of coolant ports in fluid communication with the cooling plate.

19. A vehicle comprising:
a battery pack operational to present a direct current;
a traction motor operational to generate a torque in response to an alternating current; and
a traction inverter electrically coupled between the battery pack and the traction motor and operational to convert the direct current into the alternating current, wherein the traction inverter includes:
a housing that defines a first axis, an inlet vent, and an outlet vent;
a plurality of power transistors disposed within the housing;
a plurality of busbars disposed within the housing; and
a plurality of flow guides disposed within the housing, wherein the plurality of flow guides:
isolate the plurality of power transistors pneumatically from the plurality of busbars; and
direct an airflow into the housing through the inlet vent, across the plurality of busbars in a direction parallel to the first axis and out of the housing through the outlet vent.

20. The vehicle according to claim 19, wherein:
the first axis is oriented approximately vertically in the vehicle;
the inlet vent is physically below the outlet vent; and
the airflow is solely a convection airflow.
